(19) United States
(12) Patent Application Publication
(10) Pub. No.: US 2025/0013143 A1
(43) Pub. Date: Jan. 9, 2025

(54) PELLICLE ASSEMBLY, RETICLE ASSEMBLY, RETICLE CASE, PELLICLE MEASUREMENT METHOD, AND RETICLE MEASUREMENT METHOD

(71) Applicant: Samsung Electronics Co., Ltd., Suwon-si (KR)

(72) Inventors: Yunhan LEE, Suwon-si (KR); Goonmo KOO, Suwon-si (KR); Mun Ja KIM, Suwon-si (KR)

(21) Appl. No.: 18/442,250

(22) Filed: Feb. 15, 2024

(30) Foreign Application Priority Data
Jul. 7, 2023 (KR) 10-2023-0088627

(51) Int. Cl. G03F 1/64; G03F 1/66

(52) U.S. Cl. CPC G03F 1/64; G03F 1/66

(57) ABSTRACT

A pellicle assembly may include a pellicle frame configured to provide a first opening, a pellicle on the pellicle frame, and a plurality of pellicle electrodes arranged along an edge of the pellicle and spaced apart from each other. The pellicle may include a pellicle border having a shape of a tetragonal or rectangular frame, and a pellicle membrane placed on and coupled to a top surface of the pellicle border. Each of the pellicle electrodes may include a contact member placed on and in contact with a top surface of the pellicle membrane.

### CROSS-REFERENCE TO RELATED APPLICATION

This U.S. non-provisional patent application claims priority under 35 U.S.C. § 119 to Korean Patent Application No. 10-2023-0088627, filed on Jul. 7, 2023, in the Korean Intellectual Property Office, the entire contents of which are hereby incorporated by reference.

### BACKGROUND

The present disclosure relates to a pellicle assembly, a reticle assembly, a reticle case, a pellicle measurement method, and a reticle measurement method, and in particular, to a pellicle assembly, a reticle assembly, a reticle case, a pellicle measurement method, and a reticle measurement method, which are provided to sense a state of a pellicle or reticle.

A semiconductor device may be fabricated through various processes. For example, a semiconductor device may be fabricated through an exposure process, an etching process, a deposition process, and/or a plating process. In the exposure process, a reticle may be used to form a desired pattern on a wafer. To protect the reticle from an external contamination material, a pellicle may be placed on and coupled to the reticle. The pellicle may be provided in the form of a thin film. In the case where the pellicle is damaged, a defect may be produced on a wafer after the exposure process.

### SUMMARY

An embodiment of the inventive concept provides a pellicle assembly, a reticle assembly, a reticle case, a pellicle measurement method, and a reticle measurement method, which are provided to sense a defect in a pellicle and/or reticle.

An embodiment of the inventive concept provides a pellicle assembly, a reticle assembly, a reticle case, a pellicle measurement method, and a reticle measurement method, which are provided to estimate the lifetime of a pellicle.

An embodiment of the inventive concept provides a pellicle assembly, a reticle assembly, a reticle case, a pellicle measurement method, and a reticle measurement method, which are used for measuring a pellicle and/or a reticle even during the transfer or storage of the pellicle or reticle.

According to an embodiment of the inventive concept, a pellicle assembly may include a pellicle frame configured to provide a first opening, a pellicle on the pellicle frame, and a plurality of pellicle electrodes arranged along an edge of the pellicle and spaced apart from each other. The pellicle may include a pellicle border having a shape of a tetragonal or rectangular frame, and a pellicle membrane placed on and coupled to a top surface of the pellicle border. Each of the pellicle electrodes may include a contact member placed on and in contact with a top surface of the pellicle membrane.

According to an embodiment of the inventive concept, a reticle assembly may include a reticle configured for an exposure process, a stage configured to support the reticle, and a plurality of reticle electrodes between the reticle and the stage. The reticle may include a top surface, including a mask pattern thereon, and a bottom surface spaced apart from the top surface. Each of the reticle electrodes may be in contact with the bottom surface of the reticle, and the reticle electrodes may be arranged along an edge of the bottom surface of the reticle and spaced apart from each other.

According to an embodiment of the inventive concept, a reticle case may include a lower POD and an upper POD placed on and coupled to the lower POD. The lower POD may include a lower POD body configured to provide a lower insertion hole and a plurality of lower supporting electrodes that extend upward from a bottom surface of the lower POD body defining the lower insertion hole. The lower supporting electrodes may be arranged along a corner of a tetragonal or rectangular shape and spaced apart from each other, when viewed in a plan view.

According to an embodiment of the inventive concept, a pellicle measurement method may include supplying a current to two pellicle electrodes, which are included in a plurality of pellicle electrodes spaced apart from each other along an edge of a pellicle membrane, measuring a potential difference between a pair of pellicle electrodes, which are chosen from the plurality of pellicle electrodes, and measuring an impedance of the pellicle membrane.

According to an embodiment of the inventive concept, a reticle measurement method may include supplying a current to two reticle electrodes, which are included in a plurality of reticle electrodes spaced apart from each other along an edge of a bottom surface of a reticle, measuring a potential difference between a pair of the plurality of reticle electrodes, which are chosen from the plurality of reticle electrodes, and measuring an impedance of the reticle.

### BRIEF DESCRIPTION OF THE DRAWINGS

FIG. 1 is a schematic diagram illustrating an exposure apparatus according to an embodiment of the inventive concept.

FIG. 2 is a perspective view illustrating a reticle assembly according to an embodiment of the inventive concept.

FIG. 3 is an exploded perspective view illustrating a reticle assembly according to an embodiment of the inventive concept.

FIG. 4 is a sectional view illustrating a reticle assembly according to an embodiment of the inventive concept.

FIG. 5 is an enlarged sectional view illustrating a portion X of FIG. 4.

FIG. 6 is a plan view illustrating a pellicle assembly according to an embodiment of the inventive concept.

FIG. 7 is a flow chart illustrating a pellicle measurement method according to an embodiment of the inventive concept.

FIG. 8 is a flow chart illustrating a reticle measurement method according to an embodiment of the inventive concept.

FIG. 9 is an exploded perspective view illustrating a reticle case according to an embodiment of the inventive concept.

FIG. 10 is a sectional view illustrating a reticle case according to an embodiment of the inventive concept.

FIG. 11 is an enlarged sectional view illustrating a portion Y of FIG. 10.

FIG. 12 is a flow chart illustrating a pellicle measurement method according to an embodiment of the inventive concept.

FIG. 13 is a flow chart illustrating a reticle measurement method according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

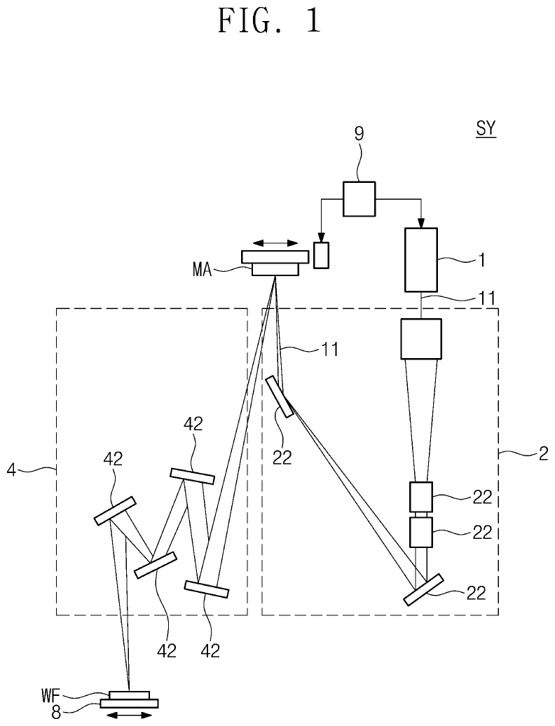

FIG. 1 is a schematic diagram illustrating an exposure apparatus according to an embodiment of the inventive concept.

Referring to FIG. 1, an exposure apparatus SY may be provided. The exposure apparatus SY may be used to perform an exposure process on a substrate. That is, the exposure apparatus SY may be configured to perform an exposure process, in which the substrate is exposed to light to form a pattern on the same. For example, the exposure apparatus SY may be configured to expose the substrate to extreme ultraviolet (EUV) light. In other words, the exposure apparatus SY may be an EUV exposure apparatus. The exposure apparatus SY may include a light source portion 1, a light condensing portion 2, a projecting portion 4, a control unit 9, and a substrate chuck 8. In some embodiments, reticle assembly MA may be placed in the exposure apparatus SY.

The light source portion 1 may be configured to generate the extreme ultraviolet light (e.g., having a wavelength of 100 nm or shorter). More specifically, the light source portion 1 may generate light with a wavelength of 13.5 nm. However, embodiments of the inventive concept are not limited to this example, and in an embodiment, the light source portion 1 may be configured to generate light with a wavelength of 100 nm to 300 nm.

The light condensing portion 2 may guide light 11, which is generated in the light source portion 1, such that the light 11 is reflected by a reticle assembly MA. For this, the light condensing portion 2 may include a condensing optical system 22. The condensing optical system 22 may include, for example, a lens and/or a mirror. The condensing optical system 22 may be configured to guide the light 11 to the reticle assembly MA through the condensing or reflection of the light 11. The light 11 may be incident into the reticle assembly MA by the light condensing portion 2. In an embodiment, the light 11 may be slantingly incident into the reticle assembly MA, i.e., the light 11 may be incident at angles that are offset from a line perpendicular to a surface of the reticle assembly MA. The reticle assembly MA may be movable within the exposure apparatus SY. For example, the reticle assembly MA may be horizontally moved under the control of the control unit 9 while the light 11 is being incident to the reticle assembly MA by the light condensing portion 2. The light 11, which is reflected from the reticle assembly MA, may propagate to the projecting portion 4.

The projecting portion 4 may be configured to project the light 11, which is reflected from the reticle assembly MA onto a substrate WF. For this, the projecting portion 4 may include a projecting optical system 42. The projecting optical system 42 may include a lens and/or a mirror. In an embodiment, the projecting optical system 42 may be disposed to project the light 11 onto the substrate WF in a reduced projection manner.

The substrate chuck 8 may support the substrate WF. In the present specification, the term ‘substrate’ may be used to represent a silicon (Si) wafer, but embodiments of the inventive concept are not limited thereto. The substrate chuck 8 may be configured to fasten the substrate WF to a specific position. For this, the substrate chuck 8 may include an electrostatic chuck (ESC), but embodiments of the inventive concept are not limited to this example. That is, the substrate chuck 8 may include a vacuum chuck or the like. The substrate WF may be loaded on the substrate chuck 8, when the reticle assembly MA is placed within the exposure apparatus SY. The reticle assembly MA may be used to form a pattern on the substrate WF, which is loaded on the substrate chuck 8. This will be described in more detail below.

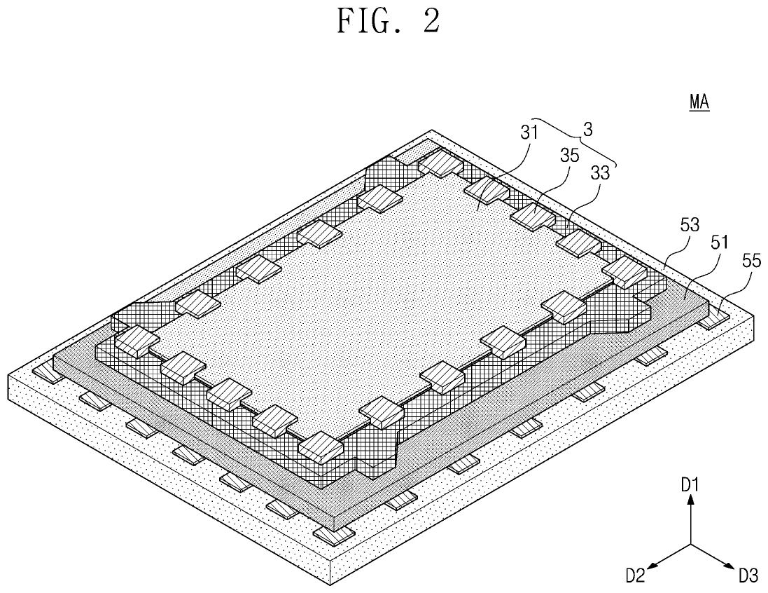

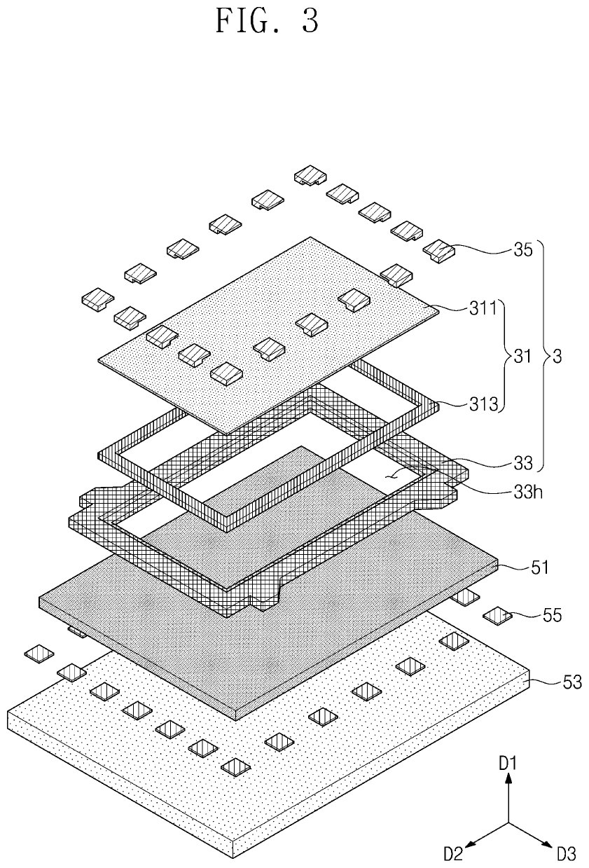

FIG. 2 is a perspective view illustrating a reticle assembly according to an embodiment of the inventive concept, and FIG. 3 is an exploded perspective view illustrating a reticle assembly according to an embodiment of the inventive concept.

In the present specification, the reference numbers D1, D2, and D3 will be used to denote a first direction, a second direction, and a third direction, respectively, which are not parallel to each other. The first direction D1 may be referred to as a vertical or upward direction. In addition, each of the second and third directions D2 and D3 may be referred to as horizontal directions, respectively.

Referring to FIGS. 2 and 3, the reticle assembly MA may include a reticle 51, a stage 53, a reticle electrode 55, and a pellicle assembly 3.

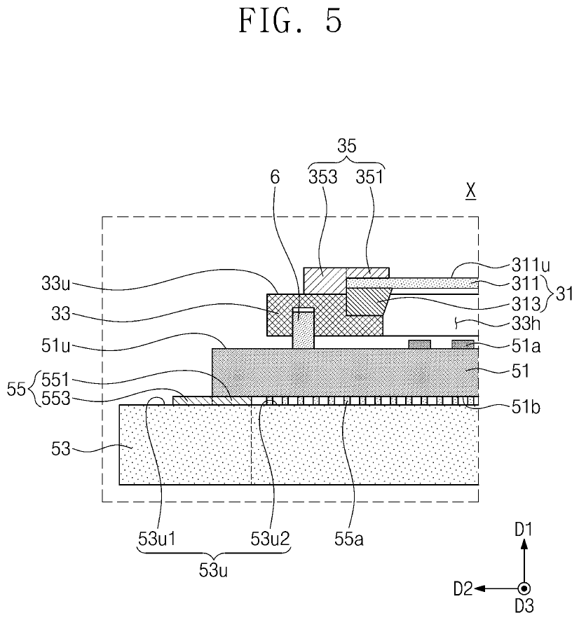

The reticle 51 may be used for an exposure process. More specifically, the reticle 51 may be provided to include a mask pattern 51a (e.g., see FIG. 5), which is used to form a desired pattern on the substrate WF of FIG. 1. That is, the reticle 51 may be a photomask. In an embodiment, the reticle 51 may be used for an exposure process that is performed using EUV light, but embodiments of the inventive concept are not limited to this example. The reticle 51 may have a rectangular shape, when viewed in a plan view. The reticle 51 will be described in more detail below.

The stage 53 may support the reticle 51. That is, the reticle 51 may be disposed on and supported by the stage 53. For this, the stage 53 may include an electrostatic chuck (ESC). In this case, the stage 53 may include a chuck electrode (not shown). An electrostatic force exerted by the stage 53 may be used to fasten the reticle 51 to a specific position on the stage 53. However, embodiments of the inventive concept are not limited to this example, and in an embodiment, the stage 53 may include a vacuum chuck or the like. The stage 53 may have a rectangular shape when viewed in a plan view, but embodiments of the inventive concept are not limited to this example. The stage 53 will be described in more detail below.

The reticle electrode 55 may be connected to the reticle 51. For example, the reticle electrode 55 may be in contact with a bottom surface of the reticle 51. A current may be supplied to the reticle 51 through the reticle electrode 55. The reticle electrode 55 may be formed of or include at least one or more conductive materials. For example, the reticle electrode 55 may be formed of or include one or more metallic materials. More specifically, the reticle electrode 55 may be formed of or include copper (Cu), silver (Ag), and/or platinum (Pt). At least a portion of the reticle electrode 55 may be placed between the reticle 51 and the stage 53. In an embodiment, a plurality of reticle electrodes 55 may be provided. The reticle electrodes 55 may be arranged along an edge of the reticle 51 and may be spaced apart from each other. For example, the reticle electrodes 55 may be arranged along an edge of the bottom surface of the reticle 51 and may be spaced apart from each other. More specifically, the reticle electrodes 55 may be arranged along the four corners of the reticle 51 and may be spaced apart from each other. In the following description, the reticle electrode 55 will be referred to as a singular element, for the sake of brevity, unless the context clearly indicates otherwise. The reticle electrode 55 will be described in more detail below.

The pellicle assembly 3 may be placed on and coupled to the reticle 51. The pellicle assembly 3 may include a pellicle 31, a pellicle frame 33, and a pellicle electrode 35.

The pellicle 31 may be placed on the pellicle frame 33. The pellicle 31 may be fastened to a specific position of the reticle 51 by the pellicle frame 33. The pellicle 31 may include a pellicle membrane 311 and a pellicle border 313.

The pellicle membrane 311 may protect the reticle 51. More specifically, the pellicle membrane 311 may protect the mask pattern 51a of the reticle 51 (e.g., see FIG. 5) from a contamination material, such as particles. The pellicle membrane 311 may be supported by the pellicle border 313. For example, the pellicle membrane 311 may be placed on and coupled to a top surface of the pellicle border 313. The pellicle membrane 311 may have a tetragonal or rectangular shape when viewed in a plan view, but embodiments of the inventive concept are not limited to this example. The pellicle membrane 311 may contain carbon. More specifically, the pellicle membrane 311 may include graphite, graphene, carbon nanotube (CNT), nanohorn, nano carbon flake, nanocrystalline graphite, amorphous carbon, diamond-like carbon (DLC), hydrocarbon, and/or graphene oxide. However, embodiments of the inventive concept are not limited to this example, and in an embodiment, the pellicle membrane 311 may be formed of or include various materials that have high transmittance to the EUV light. That is, the pellicle membrane 311 may include molybdenum (Mo), ruthenium (Ru), zirconium (Zr), zirconium carbide (ZrC), boron (B), boron carbide (BxCy), boron nitride (BN), titanium (Ti), tungsten (W), tungsten sulfide (WxSy), niobium (Nb), aluminum (Al), tin (Sn), zinc (Zn), and/or nickel (Ni). If the pellicle membrane 311 is used for other purposes, other suitable materials may be used for the pellicle membrane 311.

The pellicle border 313 may support the pellicle membrane 311. The pellicle membrane 311 may be fixedly coupled to the top surface of the pellicle border 313. The pellicle border 313 may have the shape of a tetragonal or rectangular frame. Thus, at a center of the pellicle border 313, a portion of the pellicle membrane 311 may be exposed toward the reticle 51. The pellicle border 313 will be described in more detail below.

The pellicle frame 33 may support the pellicle 31. The pellicle 31 may be fastened to a specific position on the reticle 51 by the pellicle frame 33. The pellicle frame 33 may provide a first opening 33h. The first opening 33h may have a tetragonal or rectangular shape when viewed in a plan view. The pellicle membrane 311 may be exposed to the reticle 51 through the first opening 33h. Light may pass through the pellicle membrane 311 and may be incident into the reticle 51. The light, which is reflected by the reticle 51, may pass through the pellicle membrane 311 again.

The pellicle electrode 35 may be connected to the pellicle 31. For example, the pellicle electrode 35 may be coupled to the pellicle membrane 311 and/or the pellicle border 313. More specifically, at least a portion of the pellicle electrode 35 may be provided on and may be in contact with a top surface of the pellicle membrane 311. The pellicle electrode 35 may be formed of or include one or more conductive materials. For example, the pellicle electrode 35 may be formed of or include one or more metallic materials. More specifically, the pellicle electrode 35 may be formed of or include copper (Cu), silver (Ag), and/or platinum (Pt). In an embodiment, a plurality of pellicle electrodes 35 may be provided. The pellicle electrodes 35 may be arranged along an edge of the pellicle 31 and may be spaced apart from each other. For example, the pellicle electrodes 35 may be arranged along an edge of the top surface of the pellicle membrane 311 and may be spaced apart from each other. More specifically, the pellicle electrodes 35 may be arranged along four corners of the pellicle membrane 311 and may be spaced apart from each other. In the following description, the pellicle electrode 35 will be referred to as a singular element, for the sake of brevity, unless the context clearly indicates otherwise. The pellicle electrode 35 will be described in more detail below.

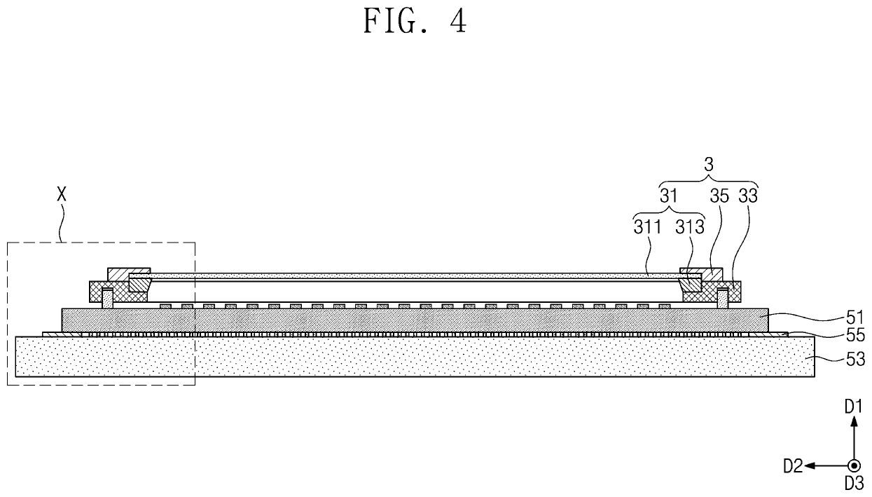

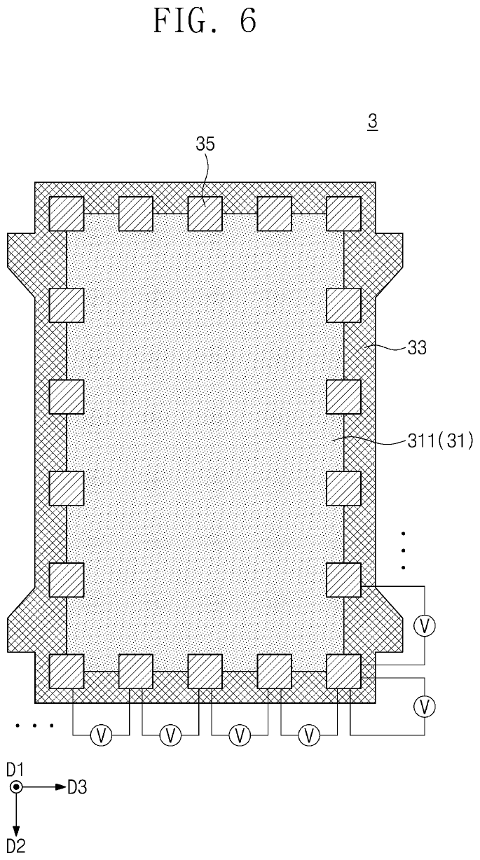

FIG. 4 is a sectional view illustrating a reticle assembly according to an embodiment of the inventive concept, FIG. 5 is an enlarged sectional view illustrating a portion X of FIG. 4, and FIG. 6 is a plan view illustrating a pellicle assembly according to an embodiment of the inventive concept.

Referring to FIGS. 4, 5, and 6, the pellicle electrode 35 may include a contact member 351 and a supporting member 353.

The contact member 351 may be provided on and may be in contact with a top surface 311u of the pellicle membrane 311. The contact member 351 may be placed on the pellicle border 313. More specifically, the contact member 351 may be in contact with the top surface 311u of the pellicle membrane 311 at a position that is spaced apart from the pellicle border 313. The pellicle border 313 may support the contact member 351. Thus, it may be possible to prevent or reduce the likelihood of the pellicle membrane 311 from being damaged by the contact member 351, even when the contact member 351 is in contact with the pellicle membrane 311.

The supporting member 353 may be placed on the pellicle frame 33. The supporting member 353 may be supported by the pellicle frame 33. More specifically, the supporting member 353 may be supported by the pellicle frame 33 in a state where the supporting member 353 is in contact with a top surface 33u of the pellicle frame 33. The pellicle electrode 35 may be electrically connected to an external power source (not shown) through an outer coupling terminal (not shown) connected to the supporting member 353. The contact member 351 may extend from the supporting member 353 toward the pellicle membrane 311. A width of the contact member 351 in a horizontal direction may not be greater than a width of the pellicle border 313 in the horizontal direction. However, embodiments of the inventive concept are not limited to this example.

A level of the top surface of the pellicle border 313 may be higher in the D1 direction than a level of the top surface 33u of the pellicle frame 33. Thus, a thickness of the supporting member 353 may be greater than a thickness of the contact member 351. However, embodiments of the inventive concept are not limited to this example.

The pellicle border 313 may further provide a coupling hole (not shown). The coupling hole may be recessed upward from a bottom surface of the pellicle border 313. A coupling member 6 may be inserted in the coupling hole. The pellicle 31 may be placed on and coupled to the pellicle frame 33 by the coupling member 6 inserted in the coupling hole.

The reticle 51 may include a top surface 51u and a bottom surface 51b. The mask pattern 51a may be provided on the top surface 51u of the reticle 51. The mask pattern 51a may be exposed to the pellicle membrane 311 through the first opening 33h. The bottom surface 51b of the reticle 51 may be spaced apart from the top surface 51u of the reticle 51 in a downward direction. The reticle electrode 55 may be in contact with the bottom surface 51b of the reticle 51.

The stage 53 may include a top surface 53u. The top surface 53u of the stage 53 may include a flat surface 53u1 and a supporting surface 53u2. A burl structure 55a may be provided on the supporting surface 53u2. The burl structure 55a may support the reticle 51. More specifically, a top surface of the burl structure 55a may be in contact with the bottom surface 51b of the reticle 51 such that the reticle 51 is supported by the burl structure 55a. The flat surface 53u1 may at least partially enclose the supporting surface 53u2.

The reticle electrode 55 may include an insertion member 551 and a coupling member 553. The insertion member 551 may be placed between the flat surface 53u1 and the bottom surface 51b of the reticle 51. The insertion member 551 on the flat surface 53u1 may be in contact with the bottom surface 51b of the reticle 51. The coupling member 553 may extend from the insertion member 551 to a region outside the reticle 51. Thus, the coupling member 553 may be exposed to the outside area around the reticle 51. The reticle electrode 55 may be electrically connected to an external power source (not shown) through an outer coupling terminal (not shown) connected to the coupling member 553.

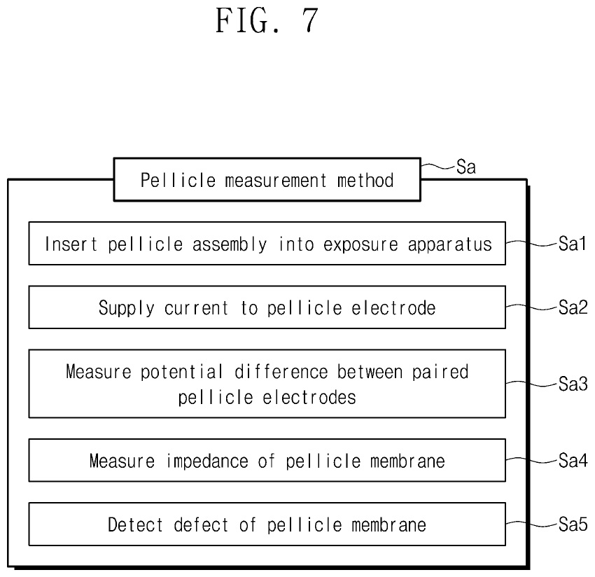

FIG. 7 is a flow chart illustrating a pellicle measurement method according to an embodiment of the inventive concept.

Referring to FIG. 7, a pellicle measurement method Sa may be provided. The pellicle measurement method Sa may be a method of measuring the physical and chemical properties of the pellicle membrane 311 (e.g., of FIG. 3) using the pellicle assembly 3 (e.g., of FIG. 2) described with reference to FIGS. 1 to 6. More specifically, the pellicle measurement method Sa may be a method of measuring the physical and chemical properties of the pellicle membrane 311 using electrical impedance tomography (EIT). For this, the pellicle measurement method Sa may include inserting a pellicle assembly into an exposure apparatus (in Sa1), supplying a current to a pellicle electrode (in Sa2), measuring a potential difference between a pair of pellicle electrodes (in Sa3), measuring an impedance of a pellicle membrane (in Sa4), and detecting a defect of the pellicle membrane (in Sa5).

Referring to FIGS. 1, 2, and 7, the inserting of the pellicle assembly into the exposure apparatus (in Sa1) may include placing the pellicle assembly 3, which is placed on and coupled to the reticle 51, in the exposure apparatus SY. The pellicle electrode 35 may be electrically connected to an external power source, when the reticle assembly MA is placed within the exposure apparatus SY. The supplying of the current to the pellicle electrode (in Sa2) may be performed when the pellicle membrane 311 (e.g., of FIG. 3) is placed within the exposure apparatus SY. That is, the current may be supplied to the pellicle electrode 35 in the exposure apparatus SY.

Referring to FIGS. 6 and 7, the supplying of the current to the pellicle electrode (in Sa2) may include supplying a current to two pellicle electrodes 35, which are included in the pellicle electrodes 35. In an embodiment, the two pellicle electrodes 35, to which the current is applied, may be adjacent to each other. More specifically, if the current is supplied to one of the pellicle electrodes 35, the current may flow to the outside through the other of the pellicle electrodes 35. The supplying of the current to the two pellicle electrodes 35 may be sequentially performed on all of the pellicle electrodes 35.

The measurement of the potential difference between the pair of pellicle electrodes (in Sa3) may be performed on two adjacent ones of the pellicle electrodes 35. However, embodiments of the inventive concept are not limited to this example, and in an embodiment, the measurement of the potential difference between the pair of pellicle electrodes (in Sa3) may be performed on two of the pellicle electrodes 35 that are not adjacent to each other. The measurement of the potential difference between the pair of pellicle electrodes (in Sa3) may be performed during supplying the current to the pellicle electrode (in Sa2). The measurement of the potential difference between the pair of pellicle electrodes (in Sa3) may be simultaneously performed on several pairs of the pellicle electrodes. That is, the potential difference may be measured from the several pairs of the pellicle electrodes during the supplying of the current to the pellicle electrode (in Sa2).

The measurement of the impedance of the pellicle membrane (in Sa4) may be performed using the current, which is supplied to the pellicle electrode, and the measured potential difference. Accordingly, the impedance and/or electrical conductivity may be measured from several regions of the pellicle membrane 311.

The defect detection of the pellicle membrane (in Sa5) may be performed using information on the measured impedance and/or electrical conductivity of the pellicle membrane 311. For example, the information on the impedance and/or electric conductivity of the pellicle membrane 311 may be used to find a position of a hole, which is formed in the pellicle membrane 311. In other embodiments, the information on the impedance and/or electric conductivity of the pellicle membrane 311 may be used to find regions of the pellicle membrane 311 with a high likelihood of defects being present. More specifically, the information on the impedance and/or electric conductivity of the pellicle membrane 311 may be used to collect data cumulatively on a region of the pellicle membrane 311 where holes are expected to occur. The collected data may be used for estimating the lifetime of the pellicle membrane 311.

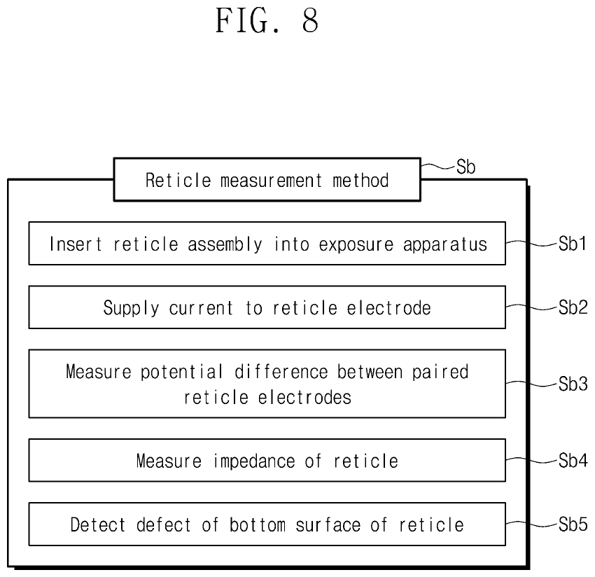

FIG. 8 is a flow chart illustrating a reticle measurement method according to an embodiment of the inventive concept.

Referring to FIG. 8, a reticle measurement method Sb may be provided. The reticle measurement method Sb may include inserting a reticle assembly into an exposure apparatus (in Sb1), supplying a current to a reticle electrode (in Sb2), measuring a potential difference between a pair of reticle electrodes (in Sb3), measuring an impedance of a reticle (in Sb4), and detecting a defect of a bottom surface of a reticle (in Sb5).

Referring to FIGS. 1, 2, and 7, the insertion of the reticle assembly into the exposure apparatus (in Sb1) may include placing the reticle assembly MA in the exposure apparatus SY. When the reticle assembly MA is placed within the exposure apparatus SY, the reticle electrode 55 may be electrically connected to an external power source. The supplying of the current to the reticle electrode (in Sb2) may be performed when the reticle assembly MA is placed within the exposure apparatus SY. That is, in the exposure apparatus SY, a current may be supplied to the reticle electrode 55.

Referring to FIGS. 2 and 7, the supplying of the current to the reticle electrode (in Sb2) may include supplying a current to two reticle electrodes 55, which are included in the reticle electrodes 55. In an embodiment, the two reticle electrodes 55, to which the current is supplied, may be adjacent to each other. More specifically, if the current is supplied to one of the paired reticle electrodes 55, the current may flow to the outside through the other of the reticle electrodes 55. The supplying of the current to the two reticle electrodes 55 may be sequentially performed on all of the reticle electrodes 55.

The measurement of the potential difference between the pair of reticle electrode (in Sb3) may be performed on two adjacent ones of the reticle electrodes 55. However, embodiments of the inventive concept are not limited to this example, and in an embodiment, the measurement of the potential difference between the pair of reticle electrodes (in Sb3) may be performed on two of the reticle electrodes 55 that are not adjacent to each other. The measurement of the potential difference between the pair of reticle electrodes (in Sb3) may be performed during supplying the current to the reticle electrode (in Sb2). The measurement of the potential difference between the pair of reticle electrodes (in Sb3) may be simultaneously performed on several pairs of the reticle electrodes. That is, the potential difference may be measured from several pairs of the reticle electrodes, during the supplying of the current to the reticle electrode (in Sb2).

The measurement of the impedance of the reticle (in Sb4) may be performed using the current, which is supplied to the reticle electrode, and the measured potential difference. Accordingly, the impedance measurement may be executed on several regions of the bottom surface 51b of the reticle 51. In an embodiment, the impedance measurement may be executed on all regions of the bottom surface 51b of the reticle 51.

The defect detection of the bottom surface of the reticle (in Sb5) may be performed using the information on the measured impedance of the bottom surface 51b of the reticle 51. For example, the information on the measured impedance of the bottom surface 51b of the reticle 51 may be used to find a region of the bottom surface 51b of the reticle 51 where a contamination material is attached. In other embodiments, the information on the impedance of the bottom surface 51b of the reticle 51 may be used to find a damaged region of the bottom surface 51b of the reticle 51.

In a pellicle assembly, a reticle assembly, a reticle case, a pellicle measurement method, and a reticle measurement method according to an embodiment of the inventive concept, it may be possible to detect a damaged portion on a pellicle. For example, it may be possible to examine whether there is a defect (e.g., a hole) in a pellicle membrane and a position of such a defect. Furthermore, it may be possible to find a region of the pellicle membrane with a high likelihood of one or more defects being present and to estimate the lifetime of the pellicle membrane. Accordingly, it may be possible to prevent or reduce the likelihood of a defect on a substrate and a contamination problem of an exposure apparatus, which may arise when performing the exposure process with a damaged pellicle membrane.

In a pellicle assembly, a reticle assembly, a reticle case, a pellicle measurement method, and a reticle measurement method according to an embodiment of the inventive concept, it may be possible to detect a defect on a bottom surface of a reticle. More specifically, it may be possible to determine whether there is a defect, such as scratch, on the bottom surface of the reticle. Accordingly, a reticle cleaning operation may be executed at an appropriate time, which allows the exposure process to be effectively carried out without unnecessary interruption using the reticle.

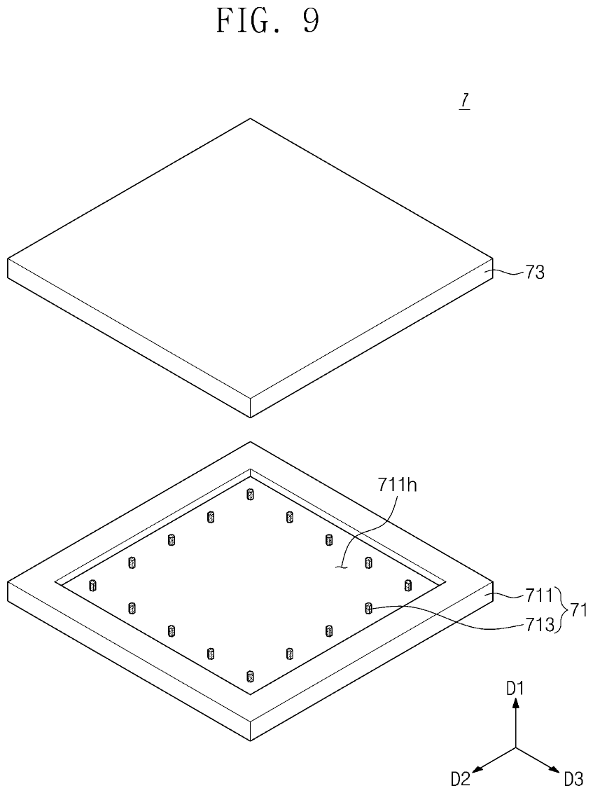

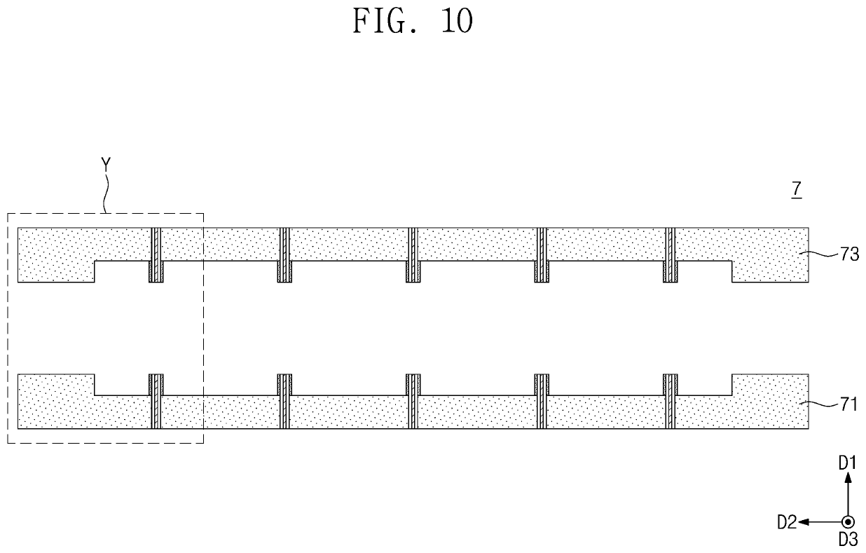

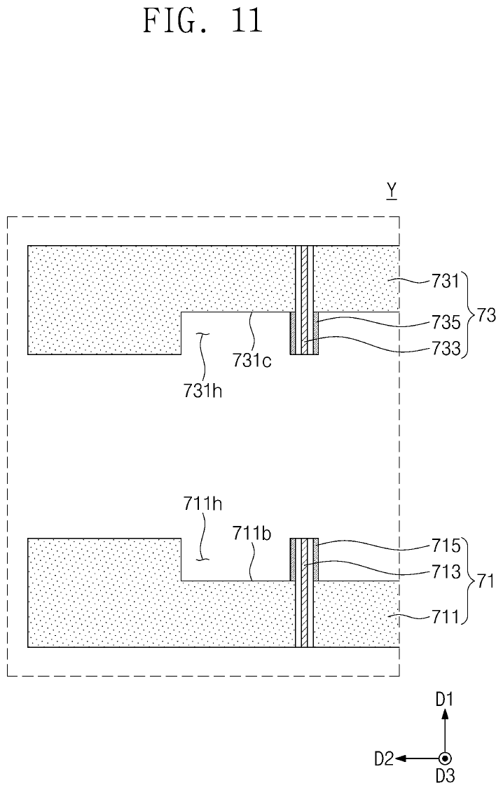

FIG. 9 is an exploded perspective view illustrating a reticle case according to an embodiment of the inventive concept, FIG. 10 is a sectional view illustrating a reticle case according to an embodiment of the inventive concept, and FIG. 11 is an enlarged sectional view illustrating a portion Y of FIG. 10.

Referring to FIGS. 9, 10, and 11, a reticle case 7 may be provided. The reticle case 7 may be configured to temporarily store the reticle assembly MA (e.g., see FIG. 2). In addition, the reticle case 7 may be used for the transfer of the reticle assembly MA. For this, the reticle case 7 may include a lower POD 71 and an upper POD 73.

The lower POD 71 may include a lower POD body 711, a lower supporting electrode 713, and a supporting member 715.

The lower POD body 711 may provide a lower insertion hole 711h. The lower insertion hole 711h may be formed to be recessed downward from a top surface of the lower POD body 711. The downward recessed surface of the lower POD body 711 will be referred to as a bottom surface 711b. A portion of the lower insertion hole 711h may be defined by the bottom surface 711b. The lower insertion hole 711h may have a tetragonal or rectangular shape when viewed in a plan view, but embodiments of the inventive concept are not limited to this example.

The lower supporting electrode 713 may extend upward from the bottom surface 711b. In other embodiments, the lower supporting electrode 713 may be vertically (D1 direction) extended to penetrate the bottom surface 711b. The lower supporting electrode 713 may be formed of or include one or more conductive materials. For example, the lower supporting electrode 713 may be formed of or include one or more metallic materials. More specifically, the lower supporting electrode 713 may be formed of or include copper (Cu), silver (Ag), and/or platinum (Pt). The lower supporting electrode 713 may be in contact with the pellicle membrane 311 (e.g., of FIG. 3). In this case, the lower supporting electrode 713 may be referred to as a pellicle electrode. In an embodiment, a plurality of lower supporting electrodes 713 may be provided. The lower supporting electrodes 713 may be arranged along a tetragonal or rectangular corner and may be spaced apart from each other when viewed in a plan view. However, in the following description, the lower supporting electrode 713 will be referred to as a singular element, for the sake of brevity.

The supporting member 715 may extend upward from the bottom surface 711b. The supporting member 715 may at least partially enclose the lower supporting electrode 713. For this, the supporting member 715 may have a hollow cylinder shape. The supporting member 715 may be formed of or include one or more insulating materials. A level of an upper end of the supporting member 715 may not be higher in the D1 direction than a level of an upper end of the lower supporting electrode 713. In an embodiment, a plurality of supporting members 715 may be provided. At least some of the supporting members 715 may be provided to at least partially enclose the lower supporting electrode 713 as described above. However, others of the supporting members 715 may not enclose the lower supporting electrode 713 unlike the embodiment described above.

The upper POD 73 may include an upper POD body 731, an upper supporting electrode 733, and an upper supporting member 735.

The upper POD body 731 may provide an upper insertion hole 731h. The upper insertion hole 731h may be formed to be recessed upward from a bottom surface of the upper POD body 731. The upward recessed surface of the upper POD body 731 will be referred to as a ceiling surface 731c. A portion of the upper insertion hole 731h may be defined by the ceiling surface 731c. The upper insertion hole 731h may have a tetragonal or rectangular shape when viewed in a plan view, but embodiments of the inventive concept are not limited to this example.

The upper supporting electrode 733 may extend upward from the ceiling surface 731c. In other embodiments, the upper supporting electrode 733 may be vertically (D1 direction) extended to penetrate the ceiling surface 731c. The upper supporting electrode 733 may be formed of or include one or more conductive materials. For example, the upper supporting electrode 733 may be formed of or include one or more metallic materials. More specifically, the upper supporting electrode 733 may be formed of or include copper (Cu), silver (Ag), and/or platinum (Pt). The upper supporting electrode 733 may be in contact with the bottom surface 51b of the reticle 51 (e.g., see FIG. 4). In this case, the upper supporting electrode 733 may be referred to as a reticle electrode. In an embodiment, a plurality of upper supporting electrodes 733 may be provided. The upper supporting electrodes 733 may be arranged along a tetragonal or rectangular corner and may be spaced apart from each other, when viewed in a plan view. However, in the following description, the upper supporting electrode 733 will be referred to as a singular element, for the sake of brevity.

The upper supporting member 735 may extend upward from the ceiling surface 731c. The upper supporting member 735 may be provided to at least partially enclose the upper supporting electrode 733. For this, the upper supporting member 735 may have a hollow cylinder shape. The upper supporting member 735 may be formed of or include an insulating material. In an embodiment, a plurality of upper supporting members 735 may be provided. At least some of the upper supporting members 735 may be provided to at least partially enclose the upper supporting electrode 733 as described above. However, others of the upper supporting members 735 may not enclose the upper supporting electrode 733 unlike the embodiment described above.

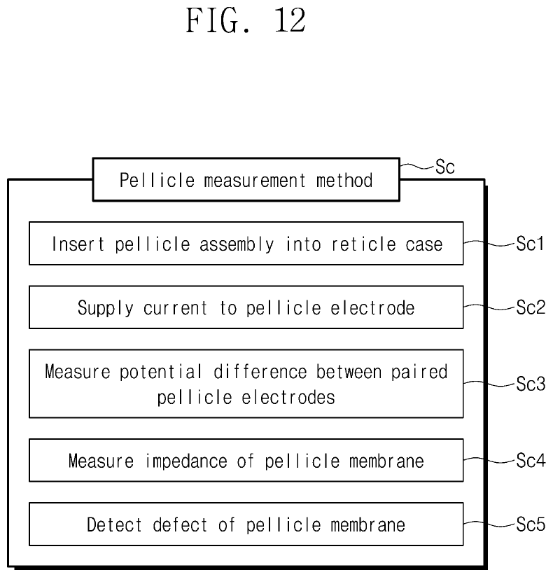

FIG. 12 is a flow chart illustrating a pellicle measurement method according to an embodiment of the inventive concept.

In the following description, for concise description, an element previously described with reference to FIGS. 1 to 11 may be identified by the same reference number without repeating an overlapping description thereof.

Referring to FIG. 12, a pellicle measurement method Sc may be provided. The pellicle measurement method Sc may be a method of measuring the physical and chemical properties of the pellicle membrane 311 described with reference to FIGS. 2 to 6 using the reticle case 7 described with reference to FIGS. 9 to 11. For this, the pellicle measurement method Sc may include inserting a pellicle assembly into a reticle case (in Sc1), supplying a current to a pellicle electrode (in Sc2), measuring a potential difference between a pair of pellicle electrodes (in Sc3), measuring an impedance of a pellicle membrane (in Sc4), and detecting a defect of the pellicle membrane (in Sc5).

Referring to FIGS. 9 to 11 and 4, the inserting of the pellicle assembly into the reticle case (in Sc1) may include inserting the reticle 51, which is coupled to the pellicle assembly 3, into the reticle case 7. If the pellicle assembly 3 is inserted into the reticle case 7, the top surface 311u of the pellicle membrane 311 may be in contact with the lower supporting electrode 713. More specifically, the lower supporting electrode 713 on the pellicle border 313 may be provided on and may be in contact with the top surface 311u of the pellicle membrane 311. In other embodiments, the lower supporting electrode 713 may be provided on and may be in contact with a top surface of the pellicle electrode 35.

The supplying of the current to the pellicle electrode (in Sc2), the measurement of the potential difference between the pair of pellicle electrodes (in Sc3), the measurement of the impedance of the pellicle membrane (in Sc4), and the defect detection of the pellicle membrane (in Sc5) may be substantially the same or similar to those in the embodiment described with reference to FIG. 7. In an embodiment, the lower supporting electrode 713 in this process may serve as a substitute for the role of the pellicle electrode 35 described with reference to FIG. 4. In this case, the pellicle assembly 3 may not include the pellicle electrode 35. In other embodiments, a current may be supplied to the pellicle electrode 35 by the lower supporting electrode 713.

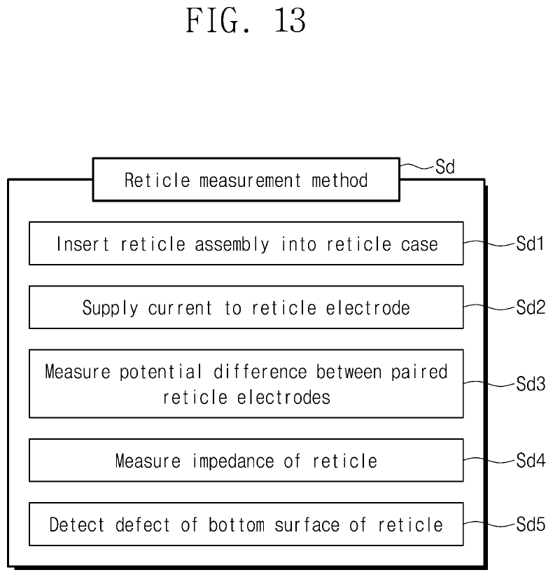

FIG. 13 is a flow chart illustrating a reticle measurement method according to an embodiment of the inventive concept.

In the following description, for concise description, an element previously described with reference to FIGS. 1 to 12 may be identified by the same reference number without repeating an overlapping description thereof.

Referring to FIG. 13, a reticle measurement method Sd may be provided. The reticle measurement method Sd may be a method of measuring the physical and chemical properties of the reticle 51 described with reference to FIGS. 2 to 6 using the reticle case 7 described with reference to FIGS. 9 to 11. For this, the reticle measurement method Sd may include inserting a reticle assembly into a reticle case (in Sd1), supplying a current to a reticle electrode (in Sd2), measuring a potential difference between a pair of reticle electrodes (in Sd3), measuring an impedance of a reticle (in Sd4), and detecting a defect of a bottom surface of the reticle (in Sd5).

Referring to FIGS. 4, 11, and 13, the inserting of the reticle assembly into the reticle case (in Sd1) may include inserting the reticle 51 into the reticle case 7. If the reticle 51 is inserted into the reticle case 7, the bottom surface 51b of the reticle 51 may be in contact with the upper supporting electrode 733. In other embodiments, the upper supporting electrode 733 may be provided on and may be in contact with the reticle electrode 55.

The supplying of the current to the reticle electrode (in Sd2), the measurement of the potential difference between the pair of reticle electrodes (in Sd3), the measurement of the impedance of the reticle (in Sd4), and the defect detection of the bottom surface of the reticle (in Sd5) may be substantially the same or similar to those in the embodiment described with reference to FIG. 8. In an embodiment, the upper supporting electrode 733 in this process may serve as a substitute for the role of the reticle electrode 55 described with reference to FIG. 4. In other embodiments, a current may be supplied to the reticle electrode 55 by the upper supporting electrode 733.

In a pellicle assembly, a reticle assembly, a reticle case, a pellicle measurement method, and a reticle measurement method according to an embodiment of the inventive concept, it may be possible to detect a defect of a pellicle and/or reticle during the transfer or storage of the pellicle and/or reticle. Thus, it may be possible to detect the defect in the pellicle and/or reticle in advance before performing an exposure process. This may enable the fabrication process to be performed relatively efficiently and quickly.

In a pellicle assembly, a reticle assembly, a reticle case, a pellicle measurement method, and a reticle measurement method according to an embodiment of the inventive concept, it may be possible to detect a defect in a pellicle and/or a reticle.

In a pellicle assembly, a reticle assembly, a reticle case, a pellicle measurement method, and a reticle measurement method according to an embodiment of the inventive concept, it may be possible to estimate the lifetime of a pellicle.

In a pellicle assembly, a reticle assembly, a reticle case, a pellicle measurement method, and a reticle measurement method according to an embodiment of the inventive concept, it may be possible to measure a pellicle and/or reticle during the transfer or storage of the pellicle or the reticle.

While example embodiments of the inventive concept have been particularly shown and described, it will be understood by one of ordinary skill in the art that variations in form and detail may be made therein without departing from the spirit and scope of the attached claims.

1. A pellicle assembly, comprising:
a pellicle frame configured to provide a first opening;
a pellicle on the pellicle frame; and
a plurality of pellicle electrodes arranged along an edge of the pellicle and spaced apart from each other,
wherein the pellicle comprises:
a pellicle border having a shape of a tetragonal or rectangular frame; and
a pellicle membrane placed on and coupled to a top surface of the pellicle border,
wherein each of the pellicle electrodes comprises a contact member placed on and in contact with a top surface of the pellicle membrane.

2. The pellicle assembly of claim 1, wherein each of the pellicle electrodes further comprises a supporting member, which is placed on and supported by the pellicle frame, and
wherein a perimeter portion of the pellicle membrane is between the contact member and the pellicle border and the contact member extends from the supporting member toward the pellicle membrane to contact the top surface of the pellicle membrane.

3. The pellicle assembly of claim 2, wherein the top surface of the pellicle border is between the perimeter portion of the pellicle membrane and a top surface of the pellicle frame, and
a thickness of the supporting member is greater than a thickness of the contact member.

4. The pellicle assembly of claim 1, wherein the pellicle frame further provides a coupling hole, which is recessed from a bottom surface of the pellicle frame.

5. The pellicle assembly of claim 1, wherein the pellicle membrane has a tetragonal or rectangular shape, when viewed in a plan view, and
wherein the pellicle electrodes are arranged along four corners of the pellicle membrane and spaced apart from each other.

6. A reticle assembly, comprising:
a reticle configured for an exposure process;
a stage configured to support the reticle; and
a plurality of reticle electrodes between the reticle and the stage,
wherein the reticle comprises:
a top surface including a mask pattern thereon; and
a bottom surface spaced apart from the top surface,
wherein each of the reticle electrodes is in contact with the bottom surface of the reticle, and
wherein the reticle electrodes are arranged along an edge of the bottom surface of the reticle and spaced apart from each other.

7. The reticle assembly of claim 6, wherein the reticle has a tetragonal or rectangular shape, when viewed in a plan view, and
wherein the reticle electrodes are arranged along four corners of the reticle and spaced apart from each other.

8. The reticle assembly of claim 6, wherein the stage further comprises an electrostatic chuck that has a top surface configured to support the reticle,
wherein the top surface of the electrostatic chuck comprises:
a supporting surface, on which a burl structure that is configured to support the reticle is provided; and
a flat surface at least partially enclosing the supporting surface,
wherein each of the reticle electrodes comprises an insertion member, which is placed between the flat surface and the bottom surface of the reticle.

9. The reticle assembly of claim 8, wherein each of the reticle electrodes further comprises a coupling member, which extends from the insertion member to a region outside the reticle and is exposed to the region outside the reticle.

10. The reticle assembly of claim 6, further comprising a pellicle assembly, which is placed on and coupled to the reticle,
wherein the pellicle assembly comprises a pellicle membrane.

11. The reticle assembly of claim 10, wherein the pellicle assembly further comprises:
a pellicle frame configured to support the pellicle membrane; and
a plurality of pellicle electrodes, which are arranged along an edge of the pellicle membrane and spaced apart from each other.

12. A reticle case, comprising:
a lower POD; and
an upper POD placed on and coupled to the lower POD,
wherein the lower POD comprises:
a lower POD body configured to provide a lower insertion hole; and
a plurality of lower supporting electrodes that extend upward from a bottom surface of the lower POD body defining the lower insertion hole,
wherein the lower supporting electrodes are arranged along a corner of a tetragonal or rectangular shape and spaced apart from each other, when viewed in a plan view.

13. The reticle case of claim 12, wherein the lower POD further comprises a plurality of supporting members, which extend upward from the bottom surface of the lower POD body, and
wherein at least one of the supporting members at least partially encloses a corresponding at least one of the lower supporting electrodes.

14. The reticle case of claim 13, wherein each of the plurality of supporting members comprises an insulating material, and
wherein each of the lower supporting electrodes comprises a conductive material.

15. The reticle case of claim 13, wherein a level of an upper end of each of the plurality of supporting members, which at least partially enclose the lower supporting electrodes, respectively, is at a level equal to or lower than that of an upper end of each of the lower supporting electrodes where the bottom surface of the lower POD body defines a base reference plane.

16. The reticle case of claim 12, wherein the upper POD comprises:
an upper POD body configured to provide an upper insertion hole; and
a plurality of upper supporting electrodes that extend downward from a ceiling surface of the upper POD body defining the upper insertion hole,
wherein the upper supporting electrodes are arranged along a corner of a tetragonal or rectangular shape and spaced apart from each other, when viewed in a plan view.

17-30. (canceled)
